(19) United States
(12) Patent Application Publication
(10) Pub. No.: US 2021/0333207 A1
(43) Pub. Date: Oct. 28, 2021

(54) OPTICAL MEASUREMENT DEVICE

(71) Applicant: HAMAMATSU PHOTONICS K.K., Hamamatsu-shi, Shizuoka (JP)

(72) Inventor: Tomonori NAKAMURA, Hamamatsu-shi, Shizuoka (JP)

(73) Assignee: HAMAMATSU PHOTONICS K.K., Hamamatsu-shi, Shizuoka (JP)

(21) Appl. No.: 17/273,963

(22) PCT Filed: Jun. 25, 2019
(86) PCT No.: PCT/JP2019/025229

§ 371 Date: Mar. 5, 2021

(30) Foreign Application Priority Data
Sep. 11, 2018 (JP) 2018-169563

(51) Int. Cl. G01N 21/59; G01R 31/265; G02B 6/293

(52) U.S. Cl. CPC G01N 21/5911; G02B 6/29323; G02B 6/2938; G01R 31/2656

(57) ABSTRACT

An embodiment includes a light source that generates measurement light including a first wavelength, a light source that generates stimulation light including a second wavelength, an optical coupling unit that is a WDM optical coupler including optical fibers branched between an output end and input ends, the input ends being optically coupled to an output of the light sources, and the WDM optical coupler combining the measurement light with the stimulation light and outputting the combination light from the output end, a photodetector that detects an intensity of reflected light from a DUT, a light irradiation and guide system that guides the combination light toward a measurement point on the DUT and guides the reflected light from the measurement point toward the photodetector, and a galvanometer mirror that moves the measurement point, and the optical fibers propagate light in a single mode for the first wavelength.

### TECHNICAL FIELD

The present disclosure relates to an optical measurement device that evaluates a measurement target object.

### BACKGROUND ART

In the related art, an inspection device in which a measurement target object is coaxially irradiated with measurement light and stimulation light using a confocal optical system, and a thermophysical property value of the measurement target object is derived using reflected light of the measurement light is known (see, for example, Patent Literature 1 below). This inspection device has a configuration in which measurement light and stimulation light are combined and radiated to a measurement target object using a half mirror.

### CITATION LIST

### Patent Literature

[Patent Literature 1] Japanese Unexamined Patent Publication No. 2006-308513

### SUMMARY OF INVENTION

### Technical Problem

With the inspection device of the related art as described above, it tends to be difficult to adjust an optical system such as a half mirror in order to coaxially combine measurement light and stimulation light having different wavelengths. Further, there may be deviations in the optical system due to long-term use, and an optical axis may deviate between the measurement light and the stimulation light. As a result, an irradiation position on the measurement target object may deviate between the measurement light and the stimulation light with which the measurement target object is irradiated, and the accuracy of evaluation of the measurement target object tends to deteriorate.

The embodiment has been made in view of such a problem, and an object of the embodiment is to provide an optical measurement device capable of reducing deviation of an irradiation position of measurement light and stimulation light on a measurement target object and improving accuracy of evaluation of the measurement target object.

### Solution to Problem

An aspect of the present disclosure includes a first light source that generates measurement light including a first wavelength; a second light source that generates stimulation light including a second wavelength shorter than the first wavelength; an optical coupling unit, the optical coupling unit being a WDM optical coupler, the WDM optical coupler including an optical fiber provided to be branched between an output end and first and second input ends, the first input end being optically coupled to an output of the first light source, the second input end being optically coupled to an output of the second light source, and the WDM optical coupler combining the measurement light with the stimulation light to generate a combination light and outputting the combination light from the output end; a photodetector configured to detect an intensity of reflected light or transmitted light from a measurement target object and output a detection signal; an optical system configured to guide the combination light toward a measurement point on the measurement target object and guide the reflected light or transmitted light from the measurement point toward the photodetector; and a scanning unit configured to move the measurement point, wherein the optical fiber has a property of propagating light in a single mode for at least the first wavelength.

According to the above aspect, the measurement light including the first wavelength and the stimulation light including the second wavelength shorter than the first wavelength are combined by the optical coupling unit and radiated to the measurement point on the measurement target object, and an intensity of reflected light or transmitted light from the measurement point on the measurement target object is detected. Further, the measurement point on the measurement target object is moved by the scanning unit. Since this optical coupling unit is configured of a WDM optical coupler including optical fibers, and the optical fibers have a property of propagating the measurement light in a single mode, a spot of the measurement light is stable and it is possible to reduce deviation of an optical axis between the measurement light and the stimulation light, which are light having different wavelengths in the combination light. As a result, it is possible to reduce deviation of irradiation positions of the measurement light and the stimulation light at the measurement point on the measurement target object, and to improve the accuracy of the evaluation of the measurement target object.

### Advantageous Effects of Invention

According to the embodiment, it is possible to reduce deviation of the irradiation positions of the measurement light and the stimulation light on the measurement target object and improve the accuracy of the evaluation of the measurement target object.

### BRIEF DESCRIPTION OF DRAWINGS

FIG. 1 is a schematic configuration diagram of an optical measurement device 1 according to an embodiment.

FIG. 2 is a diagram illustrating a structure of an optical coupling unit 11 of FIG. 1.

FIG. 3 is a block diagram illustrating a functional configuration of a controller 37 of FIG. 1.

FIG. 4 is a diagram illustrating an example of an output image of the optical measurement device 1.

FIG. 5 is a diagram illustrating an example of an output image according to a comparative example.

### DESCRIPTION OF EMBODIMENTS

Hereinafter, embodiments of the present invention will be described in detail with reference to the accompanying drawings. In the description, the same elements or elements having the same function are denoted by the same reference numerals, and repeated description thereof will be omitted.

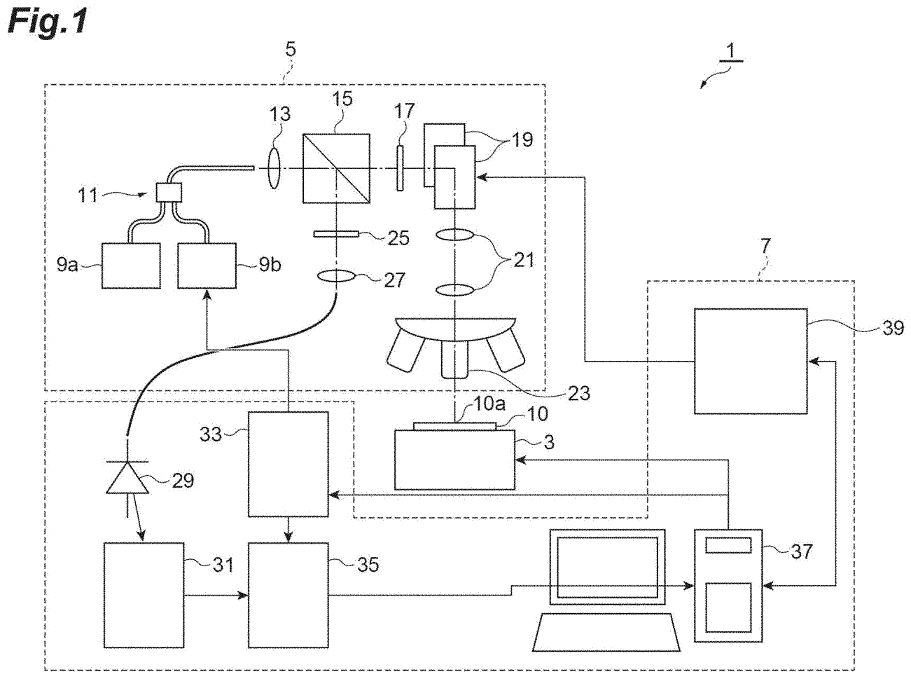

FIG. 1 is a schematic configuration diagram of an optical measurement device 1 according to an embodiment. The optical measurement device 1 illustrated in FIG. 1 is a device that performs optical measurement on a device under test (DUT) 10 that is a measurement target object such as a semiconductor device. In the present embodiment, thermoreflectance for measuring heat generation due to stimulation light in the DUT 10 is executed. Examples of the measurement target object of the optical measurement device 1 include a bare wafer, a substrate epitaxially grown at a constant doping density, a wafer substrate having a well, a diffusion region, or the like formed therein, and a semiconductor substrate having a circuit element such as a transistor formed therein.

The optical measurement device 1 includes a stage 3 on which the DUT 10 is placed, a light irradiation and guide system (optical system) 5 that radiates and guides light toward a measurement point 10a on the DUT 10 and guides reflected light from the measurement point 10a on the DUT 10, and a control system 7 that controls the light irradiation and guide system 5 and detects and processes the reflected light from the DUT 10. The stage 3 is a support part that supports the DUT 10 so that the DUT 10 faces the light irradiation and guide system 5. In this light irradiation and guide system 5, the measurement point 10a may be set near a front surface of the DUT 10 (a surface on the light irradiation and guide system 5 side) or may be set inside the DUT 10 or near a back surface of the DUT 10. Further, the stage 3 may include a moving mechanism (scanning unit) capable of moving the measurement point 10a on the DUT 10 relative to the light irradiation and guide system 5. In FIG. 1, a traveling path of light is indicated by an alternate long and short dash line, and a transfer path of a control signal and transfer paths of a detection signal and processing data are indicated by solid arrows.

The light irradiation and guide system 5 includes a light source (first light source) 9a, a light source (second light source) 9b, an optical coupling unit 11, a collimator 13, a polarized beam splitter 15, a ¼wavelength plate 17, a galvanometer mirror (scanning unit) 19, a pupil projection lens 21, an objective lens 23, an optical filter 25, and a collimator 27.

The light source 9a generates and emits light having a first wavelength and intensity suitable for detection of a change in optical characteristics (for example, a change in reflectance) due to heating in the DUT 10 as measurement light (probe light). For example, when the DUT 10 is configured of a Si (silicon) substrate, the first wavelength is 1300 nm. The light source 9b generates and emits light having a second wavelength shorter than the first wavelength and an intensity suitable for heating of the DUT 10, as stimulation light (pump light). Specifically, the light source 9b is set to generate stimulation light including a second wavelength having an energy higher than a bandgap energy of a semiconductor which is a material of the substrate constituting the DUT 10. For example, when the DUT 10 is configured of a Si substrate, the second wavelength is 1064 nm, 780 nm, or the like. Further, the light source 9b is configured to be capable of generating stimulation light of which the intensity is modulated on the basis of an electrical signal from the outside. The light source 9a and the light source 9b may be, for example, a coherent light source such as a semiconductor laser, or may be an incoherent light source such as a super luminescent diode (SLD).

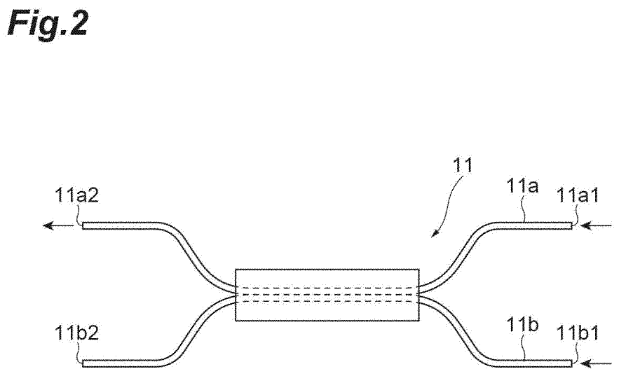

The optical coupling unit 11 is a wavelength division multiplexing (WDM) optical coupler that combines the measurement light emitted from the light source 9a with the stimulation light emitted from the light source 9b to generate combination light, and outputs the combination light. FIG. 2 illustrates an example of a structure of the optical coupling unit 11. As illustrated in FIG. 2, the optical coupling unit 11 is formed such that two optical fibers 11a and 11b are fused and stretched at central portions thereof. That is, a degree of fusion of the two optical fibers 11a and 11b in the optical coupling unit 11 is adjusted by controlling a fusion time and a fusion temperature at the time of manufacturing. As a result, the optical coupling unit 11 combines light having a first wavelength incident from one end portion (a first input end) 11a1 of the optical fiber 11a with light having a second wavelength incident from one end portion (a second input end) 11b1 of the optical fiber 11b, generates combination light including the first wavelength and the second wavelength, and emits the combination light from the other end portion (an output end) 11a2 of the optical fiber 11a. The other end portion 11b2 of the optical fiber 11b terminates, and the optical fibers 11a and 11b constitute an optical fiber branched between the end portion 11a2 and the end portions 11a1 and 11b1. In the optical coupling unit 11, the end portion 11a1 is optically coupled to an output of the light source 9a, and the end portion 11b1 is optically coupled to an output of the light source 9b.

Here, the two optical fibers 11a and 11b constituting the optical coupling unit 11 have a property of propagating light having at least the first wavelength in a single mode. That is, the optical fibers 11a and 11b are optical fibers having a core diameter set to propagate at least light having the first wavelength in the single mode. Further, the optical fibers 11a and 11b preferably have a property of propagating the light having the second wavelength in a single mode. Further, the optical fibers 11a and 11b are polarization holding fibers. The polarization holding fiber is an optical fiber in which polarization plane-holding characteristics of propagating light are enhanced due to birefringence occurring in a core.

Referring back to FIG. 1, the collimator 13 is optically coupled to the end portion 11a2 of the optical coupling unit 11, collimates the combination light emitted from the end portion 11a2 of the optical coupling unit 11, and outputs the collimated combination light to the polarized beam splitter 15. The polarized beam splitter 15 transmits a linearly polarized component of the combination light, and the ¼ wavelength plate 17 changes a polarization state of the combination light transmitted through the polarized beam splitter 15 to set the polarization state of the combination light to circularly polarized light. A galvanometer mirror 19 performs scanning with the combination light that is circularly polarized light and outputs the combination light, and the pupil projection lens 21 relays a pupil of the combination light output from the galvanometer mirror 19 from the galvanometer mirror 19 to a pupil of the objective lens 23. The objective lens 23 condenses the combination light on the DUT 10. With such a configuration, the measurement point 10a at a desired position on the DUT 10 is irradiated with the measurement light and the stimulation light combined into the combination light through scanning (movement). Further, a configuration in which the measurement point 10a can be scanned with the measurement light and the stimulation light in a range that cannot be covered by the galvanometer mirror 19 while the stage 3 is being moved may be adopted. The galvanometer mirror 19 may be replaced with a micro electro mechanical systems (MEMS) mirror, a polygon mirror, or the like as a device capable of performing scanning with the combination light.

Further, in the light irradiation and guide system 5 having the above configuration, it is possible to guide the reflected light from the measurement point 10a of the DUT 10 to the ¼ wavelength plate 17 coaxially with the combination light, and change the polarization state of the reflected light from circularly polarized light to linearly polarized light using the ¼ wavelength plate 17. Further, the linearly polarized reflected light is reflected toward the optical filter 25 and the collimator 27 by the polarized beam splitter 15. The optical filter 25 is configured to transmit only a wavelength component of the reflected light that is the same as that of the measurement light toward the collimator 27 and block a wavelength component of the reflected light that is the same as that of the stimulation light. The collimator 27 collimates the reflected light and outputs the reflected light toward the control system 7 via an optical fiber or the like.

The control system 7 includes a photodetector 29, an amplifier 31, a modulation signal source (modulation unit) 33, a network analyzer 35, a controller 37, and a laser scan controller 39.

The photodetector 29 is a photodetector element such as a photodiode (PD), an avalanche photodiode (APD), or a photomultiplier tube, and receives the reflected light guided by the light irradiation and guide system 5, detects the intensity of the reflected light, and outputs a detection signal. The amplifier 31 amplifies the detection signal output from the photodetector 29 and outputs the amplified detection signal to the network analyzer 35. The modulation signal source 33 generates an electrical signal (modulation signal) having a waveform set by the controller 37, and controls the light source 9b so that the intensity of the stimulation light is modulated on the basis of the electrical signal. Specifically, the modulation signal source 33 generates an electrical signal of a square wave having a set repetition frequency (a default frequency), and controls the light source 9b on the basis of the electrical signal. The modulation signal source 33 also has a function of repeatedly generating an electrical signal of a square wave having a plurality of repetition frequencies.

The network analyzer 35 extracts and detects a detection signal of a wavelength component corresponding to the repetition frequency on the basis of the detection signal output from the amplifier 31 and the repetition frequency set by the modulation signal source 33. Further, the network analyzer 35 detects a phase lag of the detection signal with respect to the stimulation light of which the intensity has been modulated, on the basis of the electrical signal generated by the modulation signal source 33. The network analyzer 35 inputs information on the phase lag detected for the detection signal to the controller 37. Here, the network analyzer 35 may be changed to a spectrum analyzer, may be changed to a lock-in amplifier, or may be changed to a configuration in which a digitizer and an FFT analyzer are combined.

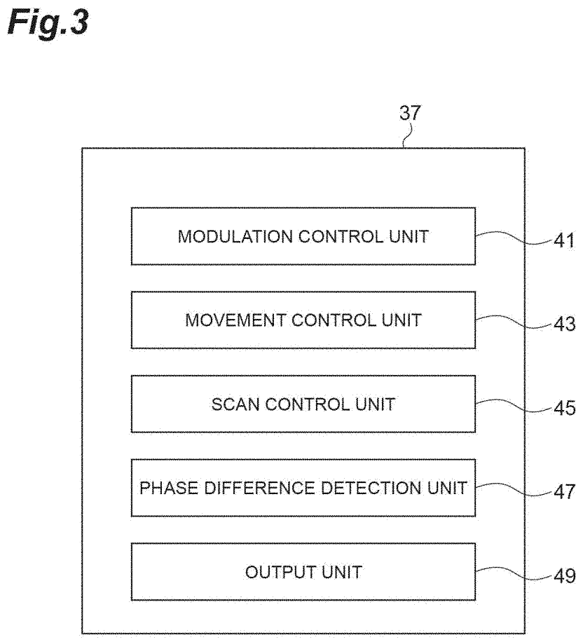

The controller 37 is a device that controls an overall operation of the control system 7 and is, physically, a control device such as a computer including a central processing unit (CPU) that is a processor, a random access memory (RAM) and a read only memory (ROM) that are recording media, a communication module, and input and output devices such as a display, a mouse, and a keyboard. FIG. 3 illustrates a functional configuration of the controller 37. As illustrated in FIG. 3, the controller 37 includes a modulation control unit 41, a movement control unit 43, a scan control unit 45, a phase difference detection unit 47, and an output unit 49 as functional components.

The modulation control unit 41 of the controller 37 sets a waveform of an electrical signal for modulating the intensity of the stimulation light. Specifically, the modulation control unit 41 sets the waveform of the electrical signal to be a square wave having a predetermined repetition frequency. The “predetermined repetition frequency” may be a frequency of a value stored in the controller 37 in advance, or may be a frequency of a value input from the outside via an input and output device.

The movement control unit 43 and the scan control unit 45 control the stage 3 and the galvanometer mirror 19 so that the DUT 10 is scanned with the combination light obtained by combining the measurement light with the stimulation light. In this case, the movement control unit 43 performs control so that the scanning is performed with the combination light while performing a phase difference detection process for each measurement point of the DUT 10.

The phase difference detection unit 47 executes the phase difference detection process for each measurement point of the DUT 10 on the basis of the information on the phase lag output from the network analyzer 35. Specifically, the phase difference detection unit 47 maps a value of the phase lag for each measurement point of the DUT 10 onto the image to generate an output image indicating a distribution of the phase lag. The output unit 49 outputs the output image generated by the phase difference detection unit 47 to the input and output device.

Hereinafter, details of a procedure of an optical measurement process in the optical measurement device 1 will be described.

First, the DUT 10 is placed on the stage 3. The DUT 10 may be placed so that the DUT 10 can be irradiated with the combination light from the front surface side or may be placed so that the DUT 10 can be irradiated with the combination light from the back surface side.

Further, the surface of the DUT 10 may be polished as necessary, and a solid immersion lens may be used for observation of the DUT 10.

Thereafter, the DUT 10 is irradiated with the combination light in which the measurement light and the stimulation light are combined, from the light irradiation and guide system 5. In this case, the light irradiation and guide system 5 is an optical system having sufficiently small chromatic aberration. In this case, an angle of the front surface or the back surface of the DUT 10 is adjusted so that the front surface or the back surface is perpendicular to an optical axis of the combination light, and a focal point of the combination light is also set to match the measurement point of the DUT 10.

Further, the stimulation light is controlled so that the intensity of the stimulation light is modulated with a square wave under the control of the controller 37. The repetition frequency of the square wave may be set on the basis of a value stored in the controller 37 in advance, or may be set on the basis of a value input from the outside via the input and output device.

Next, the photodetector 29 of the control system 7 detects the reflected light from the measurement point of the DUT 10 and generates a detection signal, and the amplifier 31 amplifies the detection signal. The network analyzer 35 of the control system 7 extracts components of the repetition frequency from the detection signal.

In addition, the network analyzer 35 of the control system 7 detects a phase lag with respect to the modulation signal of the stimulation light for a waveform of the extracted detection signal. Further, information on the detected phase lag is output from the network analyzer 35 to the controller 37. Further, the detection of the phase lag of the detection signal and the output of the information on the phase lag related thereto are repeatedly performed while the measurement point on the DUT 10 is being scanned under the control of the controller 37.

Thereafter, the controller 37 maps values of phase lags corresponding to a plurality of measurement points on the DUT 10 onto the image using the information on the phase lag regarding the plurality of measurement point, and generates data of an output image indicating a distribution of the phase lag on the DUT 10. In this case, the controller 37 may generate a pattern image of the DUT 10 on the basis of the detection signal obtained by turning off the output of the light source 9b and irradiating the DUT 10 with only the measurement light. The controller 37 outputs the output image to the input and output device on the basis of the data. With this output image, it is possible to measure spots of the heat dissipation characteristic on the DUT 10. When the pattern image is obtained, the controller 37 may superimpose the pattern image on the output image of the distribution of the phase lag to generate a superimposition image, and output the superimposition image.

According to the optical measurement device 1 described above and the optical measurement method using the same, the measurement light including the first wavelength and the stimulation light including the second wavelength shorter than the first wavelength are combined by the optical coupling unit 11 and radiated to the measurement point 10a on the DUT 10, and the intensity of the reflected light from the measurement point 10a on the DUT 10 is detected. Further, the measurement point 10a on the DUT 10 is moved by the galvanometer mirror 19. Since this optical coupling unit 11 is configured of the WDM optical coupler including the optical fibers 11a and 11b, and the optical fibers 11a and 11b have a property of propagating the measurement light in a single mode, a spot of the measurement light is stable and it is possible to reduce deviation of an optical axis and a focal point between the measurement light and the stimulation light, which are light having different wavelengths in the combination light. As a result, it is possible to reduce the deviation of the irradiation positions of the measurement light and the stimulation light at the measurement point 10a on the DUT 10, and to improve the accuracy of the evaluation of the DUT 10.

In the above embodiment, the optical fibers 11a and 11b have a property of propagating light in the single mode even for a second wavelength. Therefore, the spot of the stimulation light is also stable, and it is possible to further reduce deviation of the optical axis and the focal point between the measurement light and the stimulation light, which are light having different wavelengths in the combination light. As a result, it is possible to further improve the accuracy of the evaluation of the DUT 10.

Further, it is preferable for the optical fibers 11a and 11b to be polarization holding fibers. With such a configuration, it is possible to generate combination light while holding a polarized state of the measurement light. As a result, it is possible to prevent fluctuation of the polarized state of the measurement light, to reduce noise in the detection signal of the reflected light from the DUT 10, and to further improve the accuracy of the evaluation of the DUT 10.

Further, the second wavelength is set to a wavelength corresponding to energy higher than a bandgap energy of a semiconductor constituting the DUT 10. In this case, it is possible to efficiently generate carriers using the DUT 10 through irradiation with stimulation light, and to estimate an impurity concentration of the DUT 10 on the basis of the information on the detected phase lag.

Further, in the above embodiment, the intensity of the stimulation light is modulated with a modulation signal including a defined frequency. With such a configuration, it is possible to appropriately evaluate a heat dissipation characteristic of the DUT 10 by measuring the phase lag of the detection signal with respect to the modulation signal.

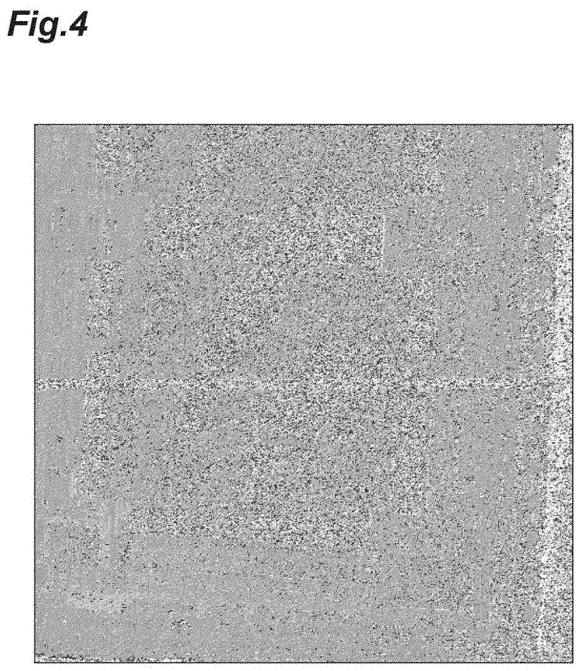

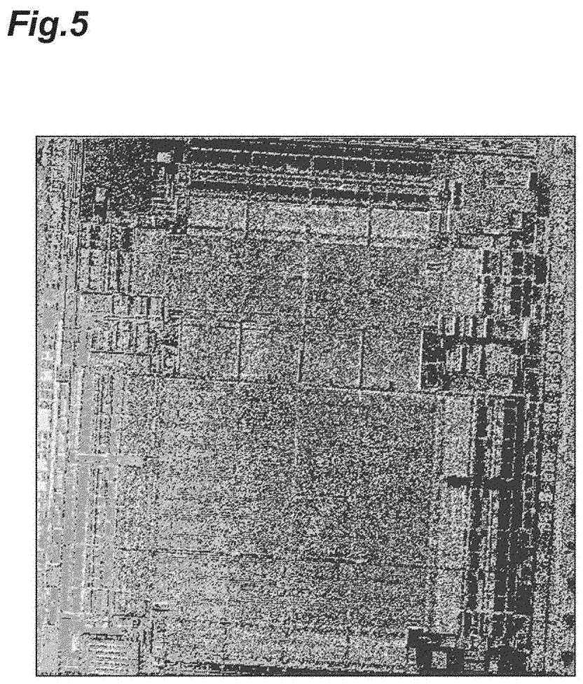

An example of the output image of the optical measurement device 1 is illustrated in comparison with the comparative example herein. FIG. 4 illustrates an example of the output image output by the optical measurement device 1, and FIG. 5 illustrates an example of an output image output for the same DUT 10 as that in FIG. 4 according to a comparative example. A difference with the optical measurement device 1 of the comparative example is that a dichroic mirror that combines the measurement light with the stimulation light on the same axis and outputs combination light is used instead of the optical coupling unit 11. In these output images, the information on the phase lag is converted to a pixel value indicating brightness and color for each pixel.

As illustrated in these results, in the comparative example, since it is easy for the irradiation positions of the stimulation signal and the measurement signal on the DUT 10 to deviate, it is difficult for the information on the phase lag due to the optical characteristics of the DUT 10 to be accurately reflected in the output image. In particular, in the example of FIG. 5, deviation is observed as a whole in a phase at the left end of the image. On the other hand, in the present embodiment, since the deviation of the irradiation position between the stimulation signal and the measurement signal on the DUT 10 is reduced, a relatively uniform phase is observed in the entire image. That is, in the present embodiment, improvement in the accuracy of the evaluation of the optical characteristics of the DUT 10 can be expected.

Although various embodiments of the present invention have been described above, the present invention is not limited to the above embodiments, and the embodiments may be modified or applied to other things in a range without changing the gist described in each claim.

The light irradiation and guide system 5 of the above embodiment is configured to be able to guide the reflected light from the DUT 10 toward the control system 7, but may be that be able to guide transmitted light generated by the measurement light being transmitted through the DUT 10 toward the control system 7. In this case, the heat dissipation characteristic of the DUT 10 is evaluated on the basis of a detection signal generated by detecting the transmitted light in the control system 7.

Further, in the above embodiment, when the photodetector 29 is configured to have sensitivity only to the measurement light, the optical filter 25 may be omitted.

Further, in the above embodiment, the measurement is performed using the stimulation light of which the intensity has been modulated with the square wave, but stimulation light of which the intensity has been modulated with a signal having another waveform such as a sine wave or a triangular wave may be used.

Further, in the above embodiment, the second wavelength may be set to a wavelength corresponding to energy lower than the bandgap energy of the semiconductor constituting the DUT 10. In this case, it is possible to curb the generation of unnecessary carriers for the substrate.

Further, in the optical measurement device 1 of the above embodiment, the controller 37 may perform a process so that a repetition frequency of the modulation signal for modulating the stimulation light is changed to a plurality of repetition frequencies, and repeats the measurement, the optical measurement is executed, and a concentration of impurities or the like at the measurement point 10a of the DUT 10 is estimated on the basis of information on a phase lag obtained for each of the plurality of repetition frequencies.

Specifically, the controller 37 estimates a frequency at which the phase lag is 45 degrees on the basis of the value of the phase lag for each of the plurality of frequencies. This frequency is called a cutoff frequency, and a time constant τ in this case is 1/(2π) times a period corresponding to this frequency. This time constant τ corresponds to a carrier lifetime inside the DUT 10. In general, the carrier lifetime τ is expressed as the following equation, in which B is a proportional constant, p₀ is a majority carrier concentration (=impurity concentration), n₀ is a minority carrier concentration, and Δn is an excess carrier concentration.

τ=1/{B(n₀+p₀+Δn)}˜1/(B·p₀)

Using this property, the controller 37 calculates the carrier lifetime τ from the frequency at which the phase lag is 45 degrees, and performs back-calculation of the above equation to calculate the impurity concentration (=p₀) as an estimated value from the carrier lifetime τ.

Further, it is not necessary for the optical measurement device 1 of the above embodiment to be necessarily that modulate the intensify of the stimulation light, and the optical measurement device 1 may be that irradiate the DUT 10 with the measurement light and the stimulation light in a state in which the DUT 10 is driven and detect the reflected light from the DUT 10 generated as a result of the irradiation, as in a configuration described in US Patent No. 2015/0002182.

In the above embodiment, it is preferable for the optical fiber to have a property of propagating the light in the single mode even for the second wavelength. In this case, the spot of the stimulation light is also stable, and it is possible to further reduce the deviation of the optical axis between the measurement light and the stimulation light, which are light having different wavelengths in the combination light. As a result, it is possible to further improve the accuracy of the evaluation of the measurement target object.

Further, it is preferable for the optical fiber to be a polarization holding fiber. With such a configuration, it is possible to generate the combination light while maintaining the polarized state of the measurement light. As a result, it is possible to reduce noise in the detection signal of the reflected light or the transmitted light from the measurement target object, and to further improve the accuracy of the evaluation of the measurement target object.

Further, it is preferable for the second wavelength to be a wavelength corresponding to energy higher than the bandgap energy of the semiconductor constituting the measurement target object. In this case, it is possible to be efficiently generate carriers using the measurement target object through irradiation with the stimulation light, and to estimate an impurity concentration of the measurement target object.

Further, it is also preferable for the second wavelength to be a wavelength corresponding to energy lower than the bandgap energy of the semiconductor constituting the measurement target object. In this case, it is possible to curb the generation of unnecessary carriers on the substrate.

Furthermore, it is preferable to further include a modulation unit that modulates the intensity of the stimulation light with a modulation signal including a defined frequency. With such a configuration, it is possible to irradiate the measurement target object with the stimulation light of which the intensity has been modulated with the modulation signal, and to appropriately evaluate the measurement target object by measuring the phase lag of the detection signal with respect to the modulation signal.

### INDUSTRIAL APPLICABILITY

The present embodiment is used for an optical measurement device that evaluates a measurement target object, and the deviation of the irradiation positions of the measurement light and the stimulation light on the measurement target object is reduced so that the accuracy of the evaluation of the measurement target object is improved.

### REFERENCE SIGNS LIST

1 Optical measurement device

5 Light irradiation and guide system (optical system)

7 Control system

9a Light source (first light source)

9b Light source (second light source)

10a Measurement point

11 Optical coupling unit

11a, 11b Optical fiber

11a1, 11b1 Input end

11a2 Output end

19 Galvanometer mirror (scanning unit)

29 Photodetector

33 Modulation signal source (modulation unit)

35 Network analyzer

37 Controller

1. An optical measurement device comprising:
a first light source configured to generate measurement light including a first wavelength;
a second light source configured to generate stimulation light including a second wavelength shorter than the first wavelength;
an optical coupler, the optical coupler being a WDM optical coupler, the WDM optical coupler including an optical fiber provided to be branched between an output end and first and second input ends, the first input end being optically coupled to an output of the first light source, the second input end being optically coupled to an output of the second light source, and the WDM optical coupler combining the measurement light with the stimulation light to generate a combination light and outputting the combination light from the output end;
a photodetector configured to detect an intensity of reflected light or transmitted light from a measurement target object and output a detection signal;
an optical system configured to guide the combination light toward a measurement point on the measurement target object and guide the reflected light or transmitted light from the measurement point toward the photodetector; and
a scanner configured to move the measurement point,
wherein the optical fiber has a property of propagating light in a single mode for at least the first wavelength.

2. The optical measurement device according to claim 1, wherein the optical fiber has a property of propagating the light in a single mode also for the second wavelength.

3. The optical measurement device according to claim 1, wherein the optical fiber is a polarization holding fiber.

4. The optical measurement device according to claim 1, wherein the second wavelength is a wavelength corresponding to an energy higher than a bandgap energy of a semiconductor constituting the measurement target object.

5. The optical measurement device according to claim 1, wherein the second wavelength is a wavelength corresponding to an energy lower than a bandgap energy of a semiconductor constituting the measurement target object.

6. The optical measurement device according to claim 1, further comprising:
modulator configured to modulate an intensity of the stimulation light with a modulation signal including a defined frequency.
